(19) United States
(12) Patent Application Publication
(10) Pub. No.: US 2020/0012150 A1
(43) Pub. Date: Jan. 9, 2020

(54) DISPLAY DEVICE AND ELECTRONIC APPARATUS

(71) Applicant: SHARP KABUSHIKI KAISHA, Sakai City, Osaka (JP)

(72) Inventors: HISASHI WATANABE, Sakai City (JP); AKIRA SAKAI, Sakai City (JP); HIROYUKI HAKOI, Sakai City (JP)

(21) Appl. No.: 16/314,828

(22) PCT Filed: Jun. 29, 2017
(86) PCT No.: PCT/JP2017/023836

§ 371 Date: Jan. 2, 2019

(30) Foreign Application Priority Data
Jul. 6, 2016 (JP) 2016-134394

(51) Int. Cl. G02F 1/1335; G02F 1/137; H01L 51/52

(52) U.S. Cl. CPC G02F 1/133555; G02F 1/133512; G02F 2203/09; H01L 51/5281; G02F 2001/133562; G02F 1/137

(57) ABSTRACT

The present invention provides a display device that can display chromatic color(s) and pattern(s) without power consumption in the non-display state (light off state) and an electronic apparatus including the display device. The display device includes a display panel and a transflective reflector disposed on a viewing surface side of the display panel. The transflective reflector includes a reflective polarizer. The reflective polarizer is chromatic and/or the transflective reflector further includes a chromatic layer on a side closer to the viewing surface than the reflective polarizer.

### TECHNICAL FIELD

The present invention relates to a display device and an electronic apparatus including the display device. The present invention specifically relates to a display device for applications such as smartphones, monitors, and televisions, and an electronic apparatus including the display device.

### BACKGROUND ART

Liquid crystal display panels have a configuration including a pair of glass substrates or the like and a liquid crystal display element sandwiched therebetween. Liquid crystal display panels, utilizing their advantages such as a thin profile, light weight, and low power consumption, are essential to items in daily life and business, such as automotive navigation systems, book readers, digital photo frames, industrial appliances, televisions, personal computers, smartphones, and tablet terminals. Also, organic electroluminescent display panels (hereinafter, also referred to as organic EL display panels) are expected to be practically used in various applications as with the liquid crystal display panels.

In a conventional electronic apparatus including a transmissive liquid crystal display or an organic EL display, an image is displayed in a display region while a region surrounding the display region (frame region), being called a frame or bezel, does not contribute to display. Meanwhile, in the power off state of such a display, being of a light emitting type, no image is displayed in the display region and the frame region remains not contributive to display.

Under the current situation, a mirror display has been proposed which includes a transflective reflector on the viewing surface side of the display and thereby can serve as a mirror in the no-display state (e.g., Patent Literatures 1 to 11). A mirror display is usable as a mirror as well as a display that is the original function. Specifically, a mirror display performs display with display light when display light is emitted from a display panel, and reflects external light to serve as a mirror when no display light is emitted from the display panel.

For the transflective reflector, an optical member with a reflective function is used, and known examples thereof include reflective polarizers such as a multilayer reflective polarizer and a wire grid reflective polarizer (e.g., Patent Literatures 12 and 13). The reflective polarizer reflects polarized incident light vibrating in the direction parallel to the reflection axis and transmits polarized incident light vibrating in the direction perpendicular to the reflection axis. Thus, the reflective polarizer can transmit light emitted from a display panel to the viewing surface side as display light and reflect external light vibrating in the direction perpendicular to the polarization direction of the display light to the viewing surface side. A mirror display including the reflective polarizer as a layer of a transflective reflector switches between the display mode (power on state) and the mirror mode (power off state) utilizing such principles.

Additionally, a mirror display has been disclosed which includes not a specular reflection surface but a diffuse reflection surface and thereby can match the surrounding environment in the mirror mode (e.g., Patent Literature 14).

### CITATION LIST

### Patent Literature

Patent Literature 1: JP 2004-085590 A
Patent Literature 2: JP 2004-125885 A
Patent Literature 3: JP 2004-86145 A
Patent Literature 4: JP 2008-90314 A
Patent Literature 5: JP 2004-177591 A
Patent Literature 6: JP 2004-118041 A
Patent Literature 7: JP 2004-118042 A
Patent Literature 8: JP H11-508377 T
Patent Literature 9: JP 2001-318374 A
Patent Literature 10: JP 2007-517568 T
Patent Literature 11: JP 2005-521086 T
Patent Literature 12: JP 2006-201782 A
Patent Literature 13: JP 2005-195824 A
Patent Literature 14: WO 2015/141350

### SUMMARY OF INVENTION

### Technical Problem

Conventional electronic apparatuses, excluding those provided with a mirror display, provide only a black display screen in the power off state, which is worthless for users and may deteriorate the designability. In particular, a black screen of a conventional electronic apparatus placed in a bright room appears out of place because the black screen fails to match the interior, walls, and the case of the display device which all have bright base colors. Namely, conventional electronic apparatuses are regarded as being valuable only in the display state. In the current trend where consumer electronics and IT equipment with high designability have been receiving the attention, a technique avoiding the provision of a black screen of the display has been required.

One of methods for achieving the technique is to keep the display in the power on state all the time. Unfortunately, this method consumes a huge amount of electricity, which inhibits application of the method to mobile terminals, particularly. Another method for achieving the technique is to use a non-light emitting type display such as a reflective LCD and an electrophoretic type display. Unfortunately, such displays are employed for only some mobile terminals and have a defect of being unavailable in dark place. This method is thus not available for all types of displays.

The present invention has been made under the current situation in the art and aims to provide a display device that can display chromatic color(s) and pattern(s) without power consumption in the non-display state (light off state), and an electronic apparatus including the display device.

### Solution to Problem

The present inventors made various studies on display devices capable of displaying chromatic color(s) and patterns) in the non-display state of the display panel and found that application of the techniques for a mirror display described above leads to a display device capable of performing display with display light when display light is emitted from the display panel and displaying chromatic color(s) and pattern(s) by reflecting external light when no display light is emitted from the display panel. The inventors then succeeded in avoiding the provision of a black screen in the power off state by disposing a transflective reflector with a reflective polarizer on the front surface of the display and allowing the reflective polarizer or a layer placed on a side closer to the viewing surface than the reflective polarizer to be chromatic. The inventors thereby successfully solved the problem to arrive at the present invention.

An aspect of the present invention may be a display device including a display panel and a transflective reflector disposed on a viewing surface side of the display panel, the transflective reflector including a reflective polarizer, the reflective polarizer being chromatic and/or the transflective reflector further including a chromatic layer on a side closer to the viewing surface than the reflective polarizer.

Another aspect of the present invention may be an electronic apparatus including the display device.

The display panel may be a liquid crystal display panel or an organic EL display panel. Some organic EL display panels for mobile applications include a polarizer to achieve improved visibility. The present invention can be particularly appropriately applied to such a case. The present invention can also be applied to an organic EL display panel without a polarizer.

The following are examples of preferred embodiments of the display device of the present invention. The respective examples may appropriately be combined with each other within the spirit of the present invention.

The display panel in the display device of the present invention includes an absorptive polarizer. The transmission axis of the absorptive polarizer and the transmission axis of the reflective polarizer may be substantially parallel to or substantially perpendicular to each other. The following are configuration examples satisfying this relationship between the transmission axis of the absorptive polarizer and the transmission axis of the reflective polarizer.

In the case where the display panel includes a polarizer (e.g., in the case where an organic electroluminescent display panel includes a circular polarizer for antireflection), a configuration in which the transmission axis of the absorptive polarizer in the display panel and the transmission axis of the reflective polarizer are substantially parallel to each other is preferred. In the case where the display panel includes a pair of absorptive polarizers whose transmission axes are perpendicular to each other (e.g., in the case where a liquid crystal display panel includes a pair of absorptive polarizers disposed in crossed Nicols), a configuration in which the transmission axis of the reflective polarizer is substantially parallel to the transmission axis of the absorptive polarizer closer to the transflective reflector (typically, on the viewing surface side) is preferred. In this configuration, the transmission axis of the polarizer farther from the transflective reflector (typically, on the back surface side) is substantially perpendicular to the transmission axis of the reflective polarizer.

Even in the case where display light emitted from the display panel is not polarized light (e.g., in the case where an organic electroluminescent display panel with no polarizer is used), the problem can be solved.

In an embodiment of the display device of the present invention, the reflective polarizer may be chromatic and/or the transflective reflector may further include a chromatic layer on a side closer to the viewing surface than the reflective polarizer. Preferably, the transflective reflector of the present invention satisfies a proportion of a minimum reflectance to a maximum reflectance in a wavelength band from 400 to 700 nm of 5% to 50%.

Preferably, the transflective reflector of the display device of the present invention in a plan view has a reflectance and/or a chromaticity changing in one direction in a wavelength band from 400 to 700 nm. Preferably, the transflective reflector has a certain pattern in a plan view.

Preferably, the reflective polarizer of the display device of the present invention is chromatic.

Preferably, the transflective reflector of the display device of the present invention further includes, on a side closer to the viewing surface than the reflective polarizer, at least one selected from the group consisting of a chromatic adhesive layer, a chromatic sheet, and a chromatic front surface plate.

Preferably, the display device of the present invention includes a light-shielding layer in a frame region on a back surface side of the reflective polarizer.

Preferably, the display device of the present invention includes an antireflection film on at least one selected from a back surface of the transflective reflector and a viewing surface of the display panel. Particularly preferably, the antireflection film is disposed on each of the back surface side of the transflective reflector and the viewing surface side of the display panel.

Preferably, the display device of the present invention includes a transparent resin filling a space between the transflective reflector and the display panel.

Preferably, the display device of the present invention includes a reflective layer between the reflective polarizer and the light-shielding layer. Preferably, the reflective layer has a reflectance in a wavelength band from 400 to 700 nm falling within a range of 1% to 10%.

Preferably, the transflective reflector of the display device of the present invention further includes a switching portion on a side closer to the viewing surface than the reflective polarizer, and the switching portion is configured to be switchable between a state of transmitting light from the viewing surface side of the display device to the display panel and a state of not transmitting light from the viewing surface side of the display device to the display panel. This configuration allows the display device to suitably switch between the on state and the off state of the switching portion in accordance with the power on state and the power off state of the display panel. The on state and the off state of the switching portion will be described later.

The switching portion includes, in the order from the back surface side, a liquid crystal display panel and an absorptive polarizer. The transmission axis of the absorptive polarizer and the transmission axis of the reflective polarizer may be substantially parallel to or substantially perpendicular to each other.

Preferably, the display panel of the display device of the present invention is a liquid crystal display panel or an organic electroluminescent display panel. For example, the display panel may be a liquid crystal display panel. With the use of a liquid crystal display panel as the display panel, the above problem can be solved. Examples of a display panel emitting polarized light as with a liquid crystal display panel include an organic electroluminescent display panel including a circular polarizer for antireflection. Also, a 3D compatible display, which allows viewing of three dimensional (3D) video images, may be used as the display panel.

The following are examples of a preferred embodiment of the electronic apparatus of the present invention. The respective examples may appropriately be combined with each other within the spirit of the present invention.

Preferably, the electronic apparatus of the present invention further includes a chromatic case housing the display device, and the chromatic case and the transflective reflector have a color difference ΔE of 6.5 or less, more preferably 3.2 or less. The color difference ΔE may satisfy the above numerical range in a plan view of the display surface. The lower limit of the color difference ΔE is not particularly limited and may be 0.

The electronic apparatus of the present invention may have, in addition to a function of switching between the display state and the non-display state in the entire screen with time, a function of operating certain region(s) in the display state and the other region(s) in the non-display state simultaneously in the same plane. For example, the display device allows a central portion of the display region to display chromatic color(s) or pattern(s) (no-image display state) and the peripheral portion to be in the image display state, whereby a no-image displayed region may be formed only in the central portion of the display region. In other words, the electronic apparatus may further include a control device that controls divided display regions. The control device can select region(s) for image display from the divided regions and can change the range and location for image display. The capability of changing the range and location for image display allows various applications achieved by combination of the function of displaying chromatic color(s) or the like and the function of displaying images) by the display panel.

### Advantageous Effects of Invention

The present invention can provide a display device having an excellent designability and capable of displaying chromatic color(s) and pattern(s) in the non-display state of a display panel, and an electronic apparatus including the display device.

### BRIEF DESCRIPTION OF DRAWINGS

FIG. 1 is a schematic cross-sectional view of a display device of Embodiment 1.

FIG. 2 includes schematic views of the display surface in the light off state of the display device of Embodiment 1.

FIG. 3(a) is a drawing showing the configuration of the display device of Embodiment 1.

FIG. 3(b) is an explanatory view showing the operation principle of the image display state of the display device of Embodiment 1.

FIG. 3(c) is an explanatory view showing the operation principle of the no-image display state of the display device of Embodiment 1.

FIG. 4 is a graph showing the reflectance (%) versus a wavelength (nm) in the display device of Embodiment 1.

FIG. 5 is a schematic cross-sectional view of a display device of a first modified example of Embodiment 1.

FIG. 6 is a schematic cross-sectional view of a display device of a second modified example of Embodiment 1.

FIG. 7 is a schematic cross-sectional view of a display device of a third modified example of Embodiment 1.

FIG. 8 is a schematic plan view of an electronic apparatus including the display device of Embodiment 1 housed in a case.

FIG. 9 is a schematic cross-sectional view of the electronic apparatus shown in FIG. 8.

FIG. 10 is a schematic view showing light paths of light incident from the periphery on the electronic apparatus including the display device of Embodiment 1 housed in a case.

FIG. 11 is a schematic cross-sectional view showing an embodiment of an electronic apparatus including the display device of Embodiment 1 housed in a case.

FIG. 12 is a schematic cross-sectional view showing an embodiment of an electronic apparatus including the display device of Embodiment 1 housed in a case.

FIG. 13 is a schematic cross-sectional view showing an embodiment of the electronic apparatus including the display device of Embodiment 1 housed in a case.

FIG. 14 is a schematic cross-sectional view of a display device of Embodiment 2.

FIG. 15 is a schematic cross-sectional view of a display device of Embodiment 3.

FIG. 16 is a schematic cross-sectional view of a display device of Embodiment 4.

FIG. 17 is a schematic cross-sectional view of a display device of Embodiment 5.

FIG. 18(a) is a drawing showing the configuration of a display device of Embodiment 5.

FIG. 18(b) is an explanatory view showing the operation principle of the image display state of the display device of Embodiment 5 from a viewpoint of display light.

FIG. 18(c) is an explanatory view showing the operation principle of the no-image display state of the display device of Embodiment 5 from a viewpoint of external light.

FIG. 18 (d) is an explanatory view showing the operation principle of the non-display state of the display device of Embodiment 5.

### DESCRIPTION OF EMBODIMENTS

The present invention is described below in more detail based on embodiments with reference to the drawings. The embodiments, however, are not intended to limit the scope of the present invention. The configurations employed in the embodiments may appropriately be combined or modified within the spirit of the present invention.

Although, in the following embodiments, cases employing a liquid crystal display panel as a display panel are described, the type of the display panel is not particularly limited and may be, for example, a plasma display panel, an organic electroluminescent display panel, an inorganic electroluminescent display panel, or a micro electromechanical system (MEMS) display.

The display state herein means, unless otherwise specified, a state in which display light is emitted from a display panel (when display is on) to pass through a transflective reflector, that is, the power on state of the display panel. The non-display state herein means, unless otherwise specified, a state in which no display light is emitted from a display panel (when display is off), that is, the power off state of the display panel. The non-display state, in which, typically, no display light is emitted and only reflected external light is viewed, is also referred to as a reflective mode. Still, as described in Embodiment 5 below, reflected external light exists also in the display state.

The reflectance herein means a reflectance in a wavelength band of visible light ranging from 400 to 700 nm, unless otherwise specified.

### Embodiment 1

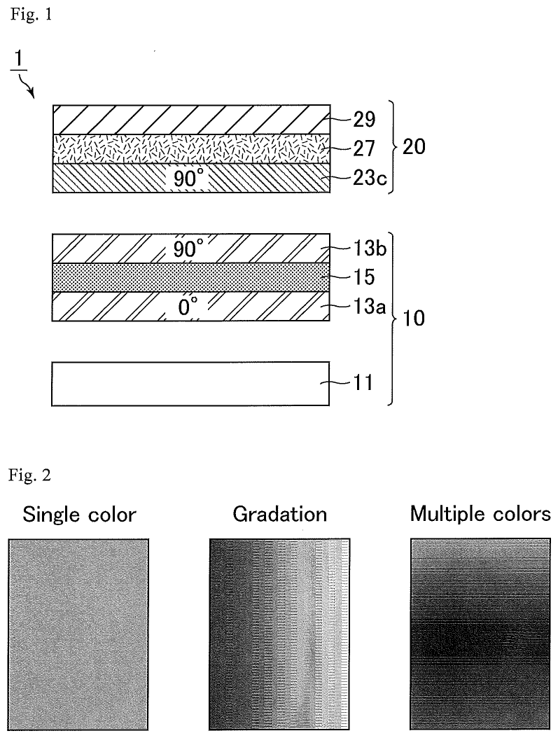

FIG. 1 is a schematic cross-sectional view of a display device of Embodiment 1.

Embodiment 1 relates to a display device 1 that includes a liquid crystal display panel 10 and a transflective reflector 20 including a chromatic reflective polarizer 23c.

The liquid crystal display panel 10 includes a backlight 11 and a liquid crystal cell 15 sandwiched between two polarizers 13a and 13b disposed in crossed Nicols. The transflective reflector 20 includes, for example, a front surface plate 29 and the chromatic reflective polarizer 23c and reflects certain polarized light but transmits polarized light vibrating in the direction perpendicular to the certain polarized light.

As shown in FIG. 1, the display device 1 includes, in the order from the back surface side to the viewing surface side, the liquid crystal display panel 10 and the transflective reflector 20. The liquid crystal display panel 10 and the transflective reflector 20 can be fixed by fitting the upper and lower edges of the transflective reflector 20 to a pair of aluminum rails which are attached to the upper and lower edges of the liquid crystal display panel 10 so as to form a frame-like structure. Here, an air layer may be or may not be formed in a slight gap between the liquid crystal display panel 10 and the transflective reflector 20. Alternatively, the reflective polarizer 23c of the transflective reflector 20 may be bonded to the liquid crystal display panel 10 via a transparent adhesive layer (e.g., acrylic resin). For example, the reflective polarizer 23c may be bonded to the front surface plate via the transparent adhesive layer such that the transmission axis of the reflective polarizer 23c is parallel to the transmission axis of the absorptive polarizer 13b. The important thing for solving the problem in the non-display state is the stacking order of the absorptive polarizers 13a and 13b and the reflective polarizer 23c (the reflective polarizer 23c should be placed on a side closer to the viewing surface than the absorptive polarizers 13a and 13b). Accordingly, disposing an isotropic transparent material such as an air layer, glass, or transparent resin, which does not particularly influence polarization states, between the absorptive polarizer 13b and the reflective polarizer 23c causes no problem. The “viewing surface” herein means, in FIG. 1, the upper surface (the surface on the side of viewer who observes the displayed contents), and thus the “viewing surface side” or “viewer side” means the upper side (the viewer side) in FIG. 1. The “back surface” means, in FIG. 1, the lower surface (the surface on the opposite side of the viewing surface), and thus the “back surface side” means the lower side (the opposite side to the viewing surface side) in FIG. 1. The same shall apply to each case.

The liquid crystal display panel 10 includes, in the order from the back surface side to the viewing surface side, the backlight 11, the absorptive polarizer 13a, the liquid crystal cell 15, and the absorptive polarizer 13b. The liquid crystal display panel 10 may be, for example, a commercially available liquid crystal television with ultra-violet induced multidomain vertical alignment (UV²A) as a photoalignment technique. The liquid crystal display panel 10 may appropriately include a bezel or the like in the frame region. Preferred examples of the bezel include one made of a plastic resin whose color is the same as the color of the transflective reflector 20.

The absorptive polarizer 13a may be bonded to the back surface side of the liquid crystal cell 15 with a transparent adhesive layer (not shown) such as acrylic resin. The absorptive polarizer 13b may be bonded to the viewing surface side of the liquid crystal cell 15 with a transparent adhesive layer (not shown) such as acrylic resin. Preferably, the azimuth of the transmission axis of the absorptive polarizer 13a is 0° and the azimuth of the transmission axis of the absorptive polarizer 13b is 90° when the azimuths are defined to be positive (+) in the counterclockwise direction from the long side of the liquid crystal display panel 10 as a reference line. In other words, the transmission axes of the absorptive polarizer 13a and the absorptive polarizer 13b are preferably disposed in crossed Nicols. Hereinafter, the azimuths of axes are described according to the above definition. Also, the drawings show the azimuths of transmission axes based on this definition. The viewing surface side of the absorptive polarizer 13b may have undergone not antireflection treatment but anti-glare treatment, for example.

The absorptive polarizer 13b disposed on the viewing surface side of the liquid crystal display panel 10 may be excluded and the functions thereof may alternatively be conducted by the reflective polarizer 23c disposed in the transflective reflector 20. Yet, since the degree of polarization of a reflective polarizer is typically lower than that of an absorptive polarizer, exclusion of the absorptive polarizer 13b causes a decrease in the contrast ratio of the liquid crystal display panel 10 in the display state. Conversely, a sufficient degree of polarization of the reflective polarizer 23c allows exclusion of the absorptive polarizer 13b without reducing the contrast ratio in the display state. In order to exclude the absorptive polarizer 13b, the degree of polarization of the reflective polarizer 23c is preferably 90% or higher (contrast ratio of 10 or higher), more preferably 99% or higher (contrast ratio of 100 or higher).

The transflective reflector 20 includes, in the order from the back surface side to the viewing surface side, the reflective polarizer 23c as a transflective reflector layer, an adhesive layer 27, and the front surface plate 29 as a transparent substrate holding the transflective reflector layer. The adhesive layer 27 bonds the reflective polarizer 23c and the front surface plate 29 together and may be, for example, an acrylic adhesive.

The front surface plate 29 is not particularly limited as long as it is made of a transparent material, and typical examples include glass, acrylic resin, and polycarbonate resin. The front surface plate 29 is made of preferably glass, more preferably toughened glass, from the viewpoint of achieving good flatness and good rigidity of the transflective reflector. The thickness of the front surface plate 29 is preferably 0.5 to 4 mm, for example, 2.5 mm, but may be thinner than 0.5 mm or thicker than 4 mm. From the viewpoint of allowing the transflective reflector 20 to function as a mirror, preferably, no antireflection film is disposed on the viewing surface side of the front surface plate 29. Alternatively, the front surface plate may be excluded. The same shall apply to the following embodiments.

The reflective polarizer 23c may be, for example, a chromatic reflective polarizer obtained by dyeing a multilayer reflective polarizer (trade name: DBEF) available from Sumitomo 3M Ltd. The dyeing means a process in which a dye is dispersed in water, a film is immersed in the dispersion, and thereby the dye soaks into the film. The “chromatic color” may be any chromatic color. From the viewpoint of reducing the influence by the color in the display state of the display panel, a color with a high brightness and a low saturation is preferred. More preferred examples are yellowish colors and sky bluish (cyan) colors.

The reflective polarizer 23c is disposed such that the azimuth of the transmission axis is 90°. The reflective polarizer 23c may be a wire grid reflective polarizer. Examples of the wire grid reflective polarizer include those disclosed in Patent Literatures 12 and 13. The transmission axis of the absorptive polarizer 13a (azimuth: 0°) and the transmission axis of the reflective polarizer 23c (azimuth: 90°) are substantially perpendicular to each other. The transmission axis of the absorptive polarizer 13b (azimuth: 90°) and the transmission axis of the reflective polarizer 23c (azimuth: 90°) are substantially parallel to each other. The expression two directions are substantially perpendicular to each other herein means that the two directions form an angle within the range of 90±3°, preferably 90±1°, more preferably 90±0.5°. The expression two directions are substantially parallel to each other herein means that the two directions form an angle within the range of 0±3°, preferably 0±1°, more preferably 0±0.5°.

FIG. 2 includes schematic views of the display surface in the light off state of the display device of Embodiment 1. As shown in FIG. 2, the transflective reflector may have a surface with a single color, multiple colors, or gradation between light and dark colors. The surface may have pattern(s). For example, the texture of a wall paper or a timber may be reproduced on the surface. The display of Embodiment 1 has many color variations as described and thus can achieve various, designs. The same shall apply to the following embodiments.

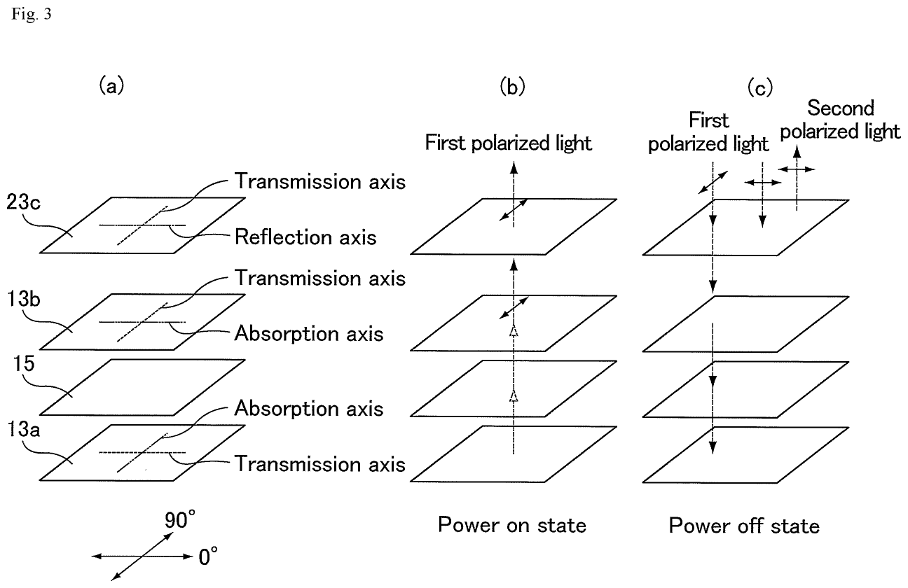

The display device of Embodiment 1 can be operated in both of the image display state and the no-image display state by the following principles. These operation principles are described with reference to FIGS. 3(a) to 3(c). FIG. 3(a) is a drawing showing the configuration of the display device of Embodiment 1. FIG. 3(b) is an explanatory view showing the operation principle of the display state of the display device of Embodiment 1. FIG. 3(c) is an explanatory view showing the operation principle of the non-display state of the display device of Embodiment 1. In FIGS. 3(a) to 3(c), part of the display device shown in FIG. 1 is taken out and the members are shown separately, for convenience. The arrows in FIGS. 3(b) and 3(c) show light paths when light passes through a member. Hereinafter, linearly polarized light that vibrates in a 90° azimuth is also referred to as first polarized light, and linearly polarized light that vibrates in a 0° azimuth is also referred to as second polarized light. The same shall apply to each case.

In the display state of the liquid crystal display panel 10, an image is displayed on the liquid crystal display panel 10 in the power on state, and a viewer sees the image of the liquid crystal display panel 10 through the transflective reflector. As shown in the light path in FIG. 3(b), light emitted from the liquid crystal display panel is first polarized light. Here, the transmission axis of the reflective polarizer 23c of the transflective reflector is set to a 90° azimuth. The first polarized light thus can pass through the reflective polarizer 23c with little loss. Therefore, the display device of Embodiment 1 can perform display with a high luminance despite including the transflective reflector.

In the non-display state (reflective mode) of the liquid crystal display panel 10, no image is displayed on the liquid crystal display panel 10 in the power off state, and the viewer sees only external light reflected by the transflective reflector. As shown in the light paths in FIG. 3 (c), the second polarized light incident on the transflective reflector from the viewing surface side enters the reflective polarizer 23c of the transflective reflector. Here, the transmission axis of the reflective polarizer 23c is set to a 90° azimuth, i.e., the reflection axis thereof is set to a 0° azimuth. Thus, almost all of the second polarized light having entered the reflective polarizer 23c is reflected by the reflective polarizer 23c. The light reflected by the reflective polarizer 23c is emitted to the viewing surface side. Thus, the display device of Embodiment 1 functions as a reflector in the power off state.

The display device of Embodiment 1 can be operated in both of the display state and the non-display state by the above principles.

Then, in the display device of Embodiment 1 with the display panel in the non-display state, the surface of the reflective polarizer 23c is recognized as a colored (chromatic) reflection surface, whereby excellent designability is achieved. Here, for example, allowing the case of the electronic apparatus to have a similar color to the reflection color of the transflective reflector achieves a design in which no display seems to exist in the non-display state of the display panel. Quantitatively, similar colors have a color difference ΔE of preferably 6.5 or less, more preferably 3.2 or less. A color difference ΔE means a distance between two points in a L*a*b* color space and is calculated by the following formula (1).

ΔE=[(ΔL*)²+(Δa*)²+(Δb*)²]^{1/2} (1)

As shown in the light paths in FIG. 3(c), the first polarized light incident on the reflective polarizer 23c of the transflective reflector from the viewer side passes through the reflective polarizer 23c. Then, the light emitted from the reflective polarizer 23c passes through the absorptive polarizer 13b and the liquid crystal cell 15 in the stated order to be absorbed by the absorptive polarizer 13a in the end. This explanation will be omitted in the following examples.

Thus, the display device of Embodiment 1 includes the colored (chromatic) reflection surface in the non-display state, thereby achieving excellent designability. For example, the display device in the non-display state can assimilate to the chromatic case. Also, an application is possible in which the display device is built in a chromatic door of a refrigerator or in the wall to be integrated with the door or the wall.

The mentioned Embodiment 1 employed a configuration in which the transmission axis of the absorptive polarizer 13b (azimuth: 90°) and the transmission axis of the reflective polarizer 23c (azimuth: 90°) are substantially parallel to each other (as a result, a configuration in which the transmission axis of the absorptive polarizer 13a (azimuth: 0°) and the transmission axis of the reflective polarizer 23c (azimuth: 90°) are substantially perpendicular to each other). As a modified example of Embodiment 1, a configuration may be employed in which the transmission axis of the absorptive polarizer on the viewing surface side of the liquid crystal display panel and the transmission axis of the reflective polarizer of the transflective reflector are substantially not parallel to each other (as a result, a configuration in which the transmission axis of the absorptive polarizer on the back surface side of the liquid crystal display panel and the transmission axis of the reflective polarizer of the transflective reflector are substantially not perpendicular to each other). Here, when the azimuth of the transmission axis of the reflective polarizer is 0°, light emitted from the liquid crystal display panel cannot pass to the viewing surface side as display light. From the viewpoint of transmitting light emitted from the liquid crystal display panel to the viewing surface side with as little loss as possible, the configuration of Embodiment 1 is preferred. The same shall apply to each case.

Although Embodiment 1 employed a configuration including the front surface plate 29, a configuration without the front surface plate 29 is allowable. An example thereof may be a configuration in which a light diffusing layer is bonded to the viewing surface side of the reflective polarizer 23c with an acrylic adhesive, thereby excluding the front surface plate 29. An alternative configuration may include the reflective polarizer 23c bonded to the back surface side of the front surface plate 29 and the light diffusing layer bonded to the viewing surface side of the front surface plate 29. The same shall apply to each case.

Still another configuration may be employed which includes a medium giving no influence on the polarization state of transmitted light (e.g., a hard coat layer, a protective film with a low birefringence) because such a medium gives no influence on the operation of the display device when disposed between the members of the display device. The same shall apply to each case.

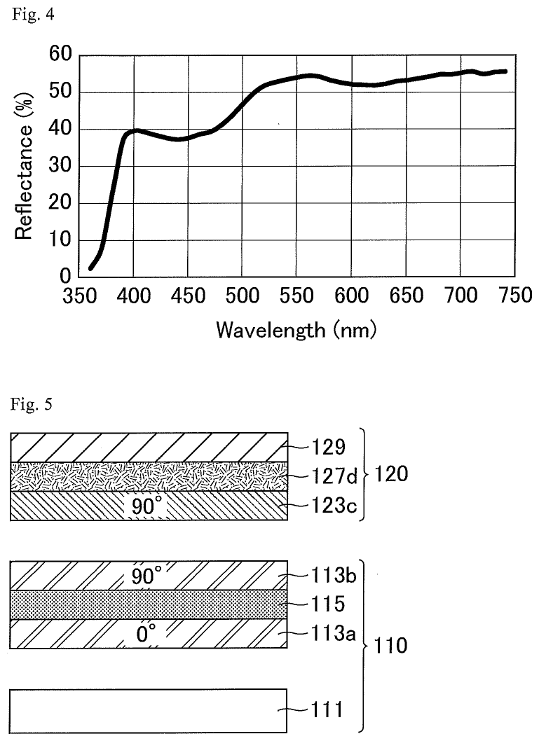

FIG. 4 is a graph showing the reflectance (%) versus a wavelength (nm) in the display device of Embodiment 1. FIG. 4 shows an example of a reflective polarizer dyed with a yellow dye. The reflection color was a color close to gold. As in the configuration of the display device of Embodiment 1, when no light diffusing layer was disposed, the viewing surface had a texture like a mirror with reflection, a texture similar to a metal, and a texture similar to gold (metal) because the reflection color was gold. The appearance of the case of the electronic apparatus was finished with a treatment giving a texture close to a mirror surface, such as plating with gold, whereby the case had a color similar to the color of the viewing surface.

### Modified Example of Embodiment 1

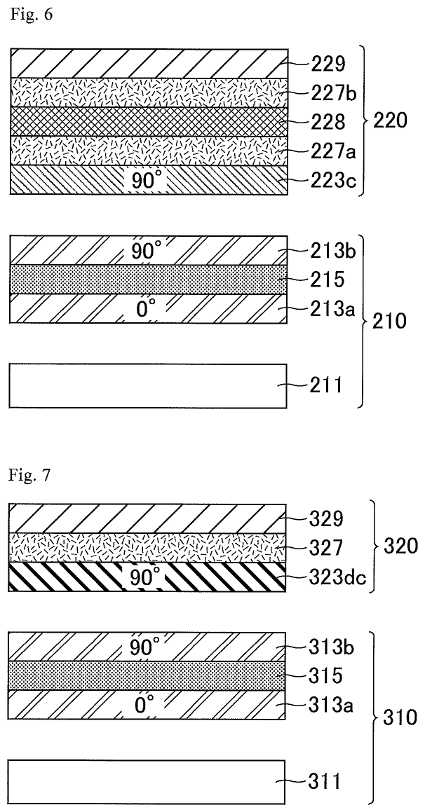

The following describes a modified example of Embodiment 1 that achieves a more mat texture (calm texture) than the display device of Embodiment 1 in the non-display state. FIG. 5 is a schematic cross-sectional view of a display device of a first modified example of Embodiment 1. The configuration of the display device is the same as that of the display device of Embodiment 1 except that the adhesive layer 27 is replaced by a diffusing adhesive layer 127d. The diffusing adhesive layer 127d may be one with fine particles of a light diffusing component dispersed in the layer. Examples of the light diffusing component include titanium oxide fine particles. FIG. 6 is a schematic cross-sectional view of a display device of a second modified example of Embodiment 1. The configuration of the display device is the same as that of the display device of Embodiment 1 except that, as shown in FIG. 6, a diffusion sheet 228 is additionally disposed and adhesive layers 227a and 227b are disposed between the diffusion sheet 228 and a reflective polarizer 223c and between the diffusion sheet 228 and a front surface plate 229, respectively. FIG. 7 is a schematic cross-sectional view of a display device of a third modified example of Embodiment 1. The configuration of the display device is the same as that of the display device of Embodiment 1 except that the reflective polarizer 23c is replaced by a reflective polarizer 323dc with a diffusing function.

From the viewpoint of achieving a display surface with a more mat texture than that of the display device of Embodiment 1 in the non-display state, preferred is using the diffusing adhesive layer 127d as an adhesive layer as shown in FIG. 5, additionally providing the diffusion sheet 228 as shown in FIG. 6, or using a reflective polarizer 323dc with a diffusing function as a reflective polarizer as shown in FIG. 7, as described above. Thus, providing a light diffusing layer such as the diffusing adhesive layer 127d, the diffusion sheet 228, or the reflective polarizer 323dc with a diffusing function can prevent reflection of lighting and objects placed in front (on the viewing surface side) of the display device. As described, a similar effect can be achieved by providing a light diffusing layer in place of the front surface plate or providing a light diffusing layer on the viewing surface side of the front surface plate. These light diffusing layers are preferred to be polarized light diffusing layers. For example, the diffusion sheet is preferred to be a polarized light diffusion sheet.

As mentioned above, when the transflective reflector was provided with a light diffusing function, the appearance of the case was obtained by, for example, yellow anodizing blasted aluminum or finishing a resin material with a yellow coating to have a texture close to the display surface.

In the display devices shown in FIG. 1 and FIG. 5 to FIG. 7, the adhesive layer may be replaced by an air layer as long as gaps between the members are physically held. The same shall apply to each case.

### (Electronic Apparatus)

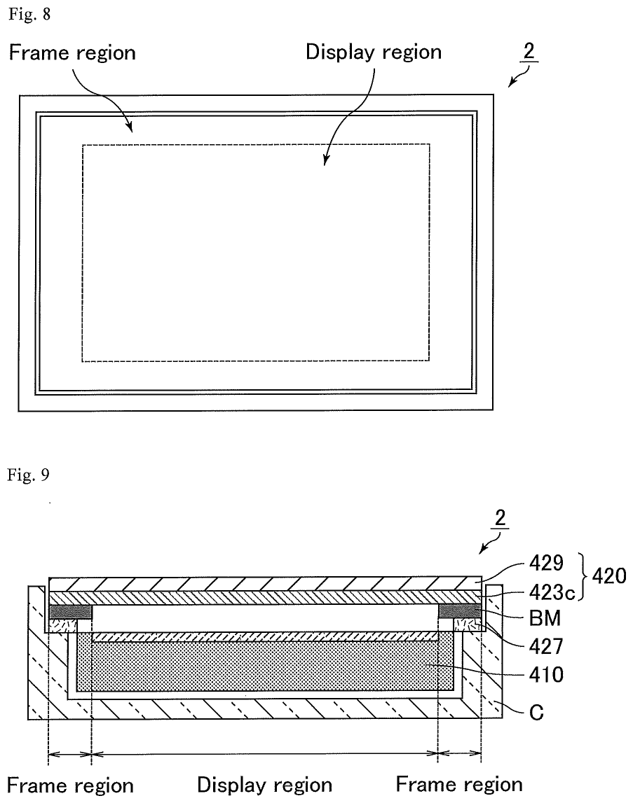

The following describes the cases where each of the display devices of Embodiment 1 and modified examples thereof is housed in a case to be produced into an electronic apparatus. FIG. 8 is a schematic plan view of an electronic apparatus including the display device of Embodiment 1 housed in a case. FIG. 9 is a schematic cross-sectional view of the electronic apparatus shown in FIG. 8. The configurations of a liquid crystal display panel 410 and a transflective reflector 420 are as described above. Preferably, the transflective reflector 420 is formed in one size larger than that of the liquid crystal display panel 410. The transflective reflector 420 is divided into a display region and a frame region. The display region is a region superimposed on the display region (also referred to as an active area) of the display device in a plan view of the display surface. The frame region is a peripheral region of the display region of the display device. In the frame region on the back surface side of the transflective reflector 420, a light-shielding layer BM is formed. The light-shielding layer BM functions to hide the frame of the liquid crystal display panel 410 and to block stray light or the like emitted from the liquid crystal display panel. The light-shielding layer BM may be formed by a widely used method, such as forming the light-shielding layer BM with a black ink by screen printing. To the light-shielding layer BM, an adhesive layer 427 is attached in order to fix the light-shielding layer BM in the case C. The case C is designed to have a similar color and a similar diffusing property to those of the transflective reflector 420. In such an electronic apparatus 2 with the display panel in the non-display state, the transflective reflector 420 and the case C seem to be integrated, which gives an impression as if the screen has disappeared.

The above description is an example of the configuration of the electronic apparatus and the present invention is not limited to this example. The following describes a problem when the display device is housed in a case and a method for solving the problem. The problem and the method for solving the problem shall apply to Embodiments 2 to 4 described below.

<Problem when Display Device is Housed in Case>

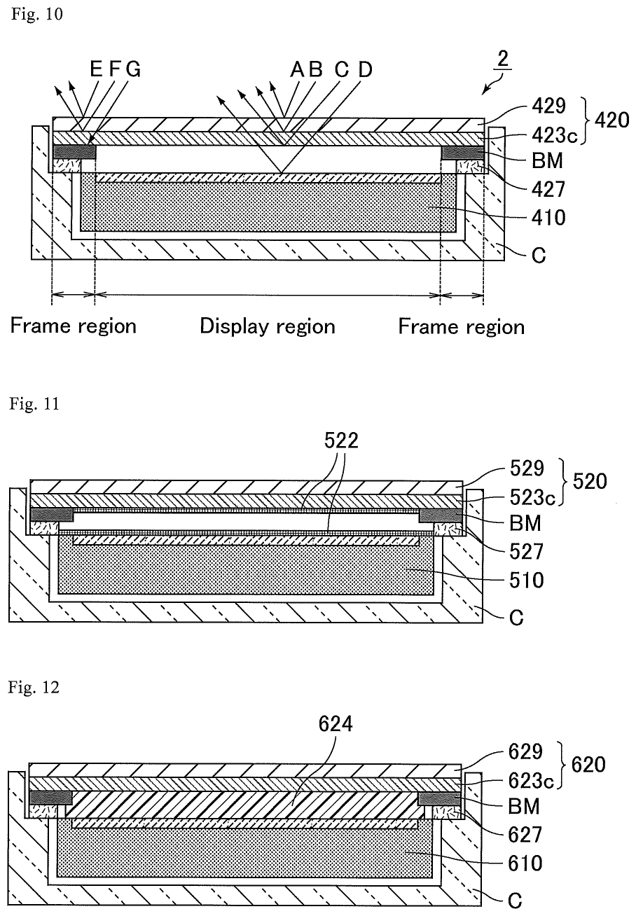

FIG. 10 is a schematic view showing light paths of light incident from the periphery on the electronic apparatus including the display device of Embodiment 1 housed in a case.

Here, a problem when the light-shielding layer BM is disposed on the transflective reflector 420 is described. In the display region, an air layer is provided on the back surface side of the reflective polarizer 423c in the transflective reflector 420. Accordingly, light paths of light incident from the periphery belong to the following four patterns.

Light A: reflected on the upper surface of the front surface plate 429

Light B: reflected on the upper surface of the reflective polarizer 423c

Light C: reflected on the lower surface of the reflective polarizer 423c

Light D: reflected on the upper surface of the liquid crystal display panel 410

The light A has a reflectance of about 4% and has a small difference in reflectance between different wavelengths. Thus, the reflected light is white.

The light B, which is reflected by the colored reflective polarizer 423c, is thus imparted with a certain color when reflected. The reflectance is 50% or less.

The light C and light D, each of which has a reflectance of about 4% and passes through the colored reflective polarizer 423c twice, allow the reflected light to have a slightly strong color.

In the frame region, the light-shielding layer BM is provided on the back surface side of the reflective polarizer 423c. Light paths of light incident from the periphery belong to the following three patterns.

Light E: reflected on the upper surface of the front surface plate 429 and corresponds to the light A

Light F: reflected by the upper surface of the reflective polarizer 423c and corresponds to the light B

Light G: absorbed by the light-shielding layer BM and not reflected

In summary, presence or absence of the light C and light D causes differences in reflectance and tinge between the display region and the frame region. This problematically causes the boundary between the display region and the frame region to be visible.

<Method for Solving Problem when Display Device is Housed in Case>

Three methods for solving the problem are proposed in the following.

FIG. 11 is a schematic cross-sectional view showing an embodiment of an electronic apparatus including the display device of Embodiment 1 housed in a case. In a first method, as shown in FIG. 11, an antireflection layer 522 is provided on the lower surface of a transflective reflector 520 and on the upper surface of a liquid crystal display panel 510. The antireflection layer 522 is obtained by forming a material with a low refractive index into a thin film or forming a moth-eye pattern with fine irregularities on a plastic film. Thereby, the reflectances of the light C and the light D come close to zero, whereby the boundary between the display region and the frame region is invisible.

FIG. 12 is a schematic cross-sectional view showing an embodiment of an electronic apparatus including the display device of Embodiment 1 housed in a case. In a second method, as shown in FIG. 12, an air layer between a transflective reflector 620 and a liquid crystal display panel 610 is filled with a material such as a transparent resin 624 whose refractive index is close to that of a polarizer. Typically, a polarizer has a refractive index of about 1.5. Thereby, the reflectances of the light C and the light D come close to zero, whereby the boundary between the display region and the frame region is invisible.

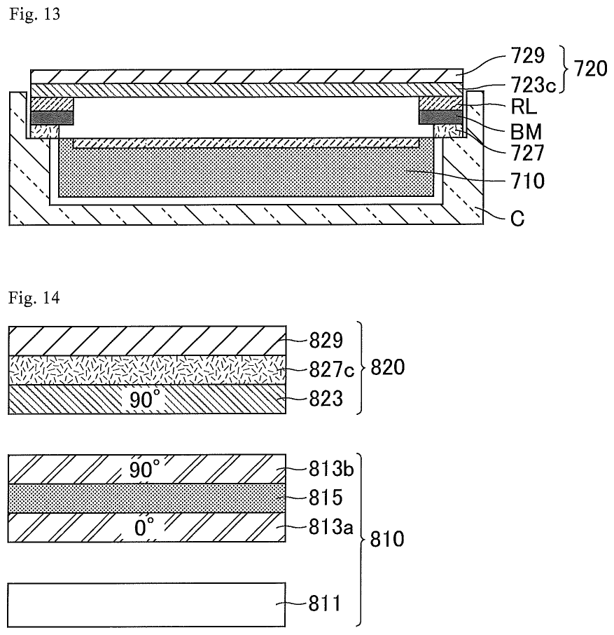

FIG. 13 is a schematic cross-sectional view showing an embodiment of an electronic apparatus including the display device of Embodiment 1 housed in a case. In a third method, between a reflective polarizer 723c and the light-shielding layer BM, a reflective layer RL is provided whose reflection characteristics are similar to those of the light C and light D. The reflectance varies depending on the tinge of the reflective polarizer 723c and is, for example, about 1% to 10%. Thereby, the boundary between the display region and the frame region is invisible. When the light-shielding layer BM is formed by a method such as screen printing, the reflective layer RL can be formed by using the same plate with a different ink, which hardly increases the cost. If stray light from a liquid crystal display panel 710 hardly causes an adverse effect, a configuration excluding the light-shielding layer BM and including only the reflective layer RL may be employed.

In an electronic apparatus obtained by using one of the problem solving methods, the screen turned gold in the non-display state of the display panel. Coating the case with a similar gold color achieved an effect in which the screen seemed to have disappeared. Plating the case with gold also achieved a similar effect. In the display state of the display panel, light emitted from the display device is slightly tinged with yellow. Thus, the emitted light is subjected to color correction by, preferably, adjusting the color of the backlight or the tinge of the liquid crystal. The term color correction means adjusting a tinge in order to achieve an appropriate white balance when displaying white.

The present embodiment presented an example in which the reflective polarizer was colored in yellow, but the reflective polarizer may be colored in any color other than yellow. However, as described, in the display state of the display panel, light emitted from the liquid crystal display panel is colored to shift the white balance. Thus, not very deep colors are preferred. Specifically, the proportion of the minimum reflectance to the maximum reflectance in a wavelength band of visible light ranging from 400 to 700 nm is preferably 50% or less. If the proportion of the minimum value to the maximum value is less than 5%, however, the color of the screen in the non-display state of the display panel may be hardly recognized.

The present embodiment has the following problem. That is, the display panel, even in the display state, unfortunately colors and reflects surrounding light, thereby possibly causing a reduction in contrast ratio of the display screen and a change of tinge. Accordingly, the electronic apparatus of the present embodiment is suitable to an apparatus used in a not too bright place such as in a room. The electronic apparatus of the present embodiment is particularly effectively applied to an interior apparatus such as a television or a desktop personal computer (PC). The electronic apparatus is also effectively used as a display device for consumer electronics such as refrigerators, washing machines, and microwave ovens.

The following are descriptions of Embodiments 2 to 5. In Embodiments 2 to 4, the reflective polarizer in the transflective reflector is not a chromatic layer.

### Embodiment 2

FIG. 14 is a schematic cross-sectional view of a display device of Embodiment 2. In Embodiment 2, an adhesive layer 827c is a chromatic layer. For example, a dye, a pigment, or the like of a certain color is kneaded in an adhesive and the resultant adhesive is applied to a release sheet. The applied adhesive is transferred on a reflective polarizer 823 and attached to a front surface plate 829. Thus, the adhesive layer 827c as a chromatic layer is formed between the front surface plate 829 and the reflective polarizer 823, whereby a colored transflective reflector 820 is completed. The configuration of the display device of Embodiment 2 is the same as that of the display device of Embodiment 1 except that the colored transflective reflector 820 is provided by employing the chromatic adhesive layer 827c instead of the chromatic reflective polarizer. The display device of Embodiment 2 works based on the same operation principles as the display device of Embodiment 1, thereby achieving the same effects.

### Embodiment 3

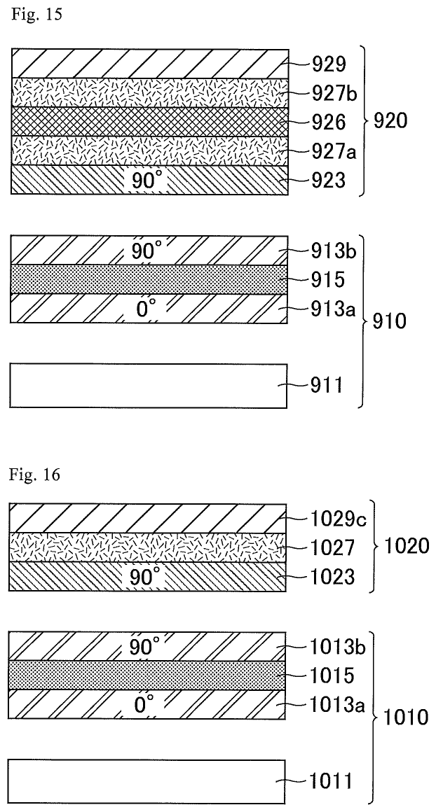

FIG. 15 is a schematic cross-sectional view of a display device of Embodiment 3. In Embodiment 3, a translucent chromatic sheet 926 is additionally provided. Examples of the chromatic sheet 926 include a dyed sheet. Specifically, a transparent resin sheet such as polyethylene terephthalate is dyed in a certain color to form a colored translucent sheet. The chromatic sheet 926 is disposed between a reflective polarizer 923 and a front surface plate 929 via adhesive layers 927a and 927b, whereby a colored transflective reflector 920 is provided. The dyed sheet for the chromatic sheet 926 used in Embodiment 3 may be replaced by a sheet colored by coating or the like. The configuration of the display device of Embodiment 3 is the same as that of the display device of Embodiment 1 except that the colored transflective reflector 920 is provided by disposing the chromatic sheet 926, instead of the chromatic reflective polarizer, between the reflective polarizer 923 and the front surface plate 929 via the adhesive layers 927a and 927b. The display device of Embodiment 3 works based on the same operation principles as the display device of Embodiment 1, thereby achieving the same effects. In Embodiment 3, some light reflection occurs in the interfaces (air interfaces) between the air layer and the transflective reflector 920 and between the air layer and the liquid crystal display panel 910. Although provision of the reflective polarizer 923 is not essential, absence of the reflective polarizer 923 causes a low reflectance so that the screen of the device looks only slightly colored. Thus, the reflective polarizer 923 is preferably provided.

### Embodiment 4

FIG. 16 is a schematic cross-sectional view of a display device of Embodiment 4. In Embodiment 4, a front surface plate 1029c is a chromatic layer. For example, a transparent resin material such as acrylic resin is dyed in a certain color and formed into a colored translucent front surface plate. The colored translucent front surface plate is bonded to a reflective polarizer 1023 via an adhesive layer 1027, whereby a colored transflective reflector 1020 is completed. The dyed front surface plate for the chromatic front surface plate 1029c used in Embodiment 4 may be replaced by a front surface plate colored by coating or the like. The configuration of the display device of Embodiment 4 is the same as that of the display device of Embodiment 1 except that the colored transflective reflector 1020 is provided by employing the chromatic front surface plate 1029c instead of the chromatic reflective polarizer. The display device of Embodiment 4 works based on the same operation principles as those of the display device of Embodiment 1, thereby achieving the same effects. In Embodiment 4, some light reflection occurs in the interfaces between the air layer and the transflective reflector 1020 and between the air layer and the liquid crystal display panel 1010. Although provision of the reflective polarizer 1023 is not essential, absence of the reflective polarizer 1023 causes a low reflectance so that the screen of the device looks only slightly colored. Thus, the reflective polarizer 1023 is preferably provided.

### Embodiment 5

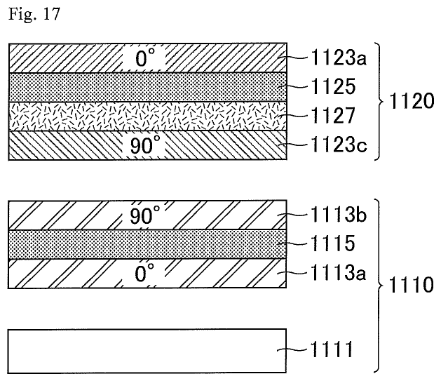

FIG. 17 is a schematic cross-sectional view of a display device of Embodiment 5. In the display device of Embodiment 5, the front surface plate in Embodiment 1 is replaced by a liquid crystal panel 1125 for switching and an absorptive polarizer 1123a is further stacked. The configuration excepting the above of the display device of Embodiment 5 is the same as that of the display device of Embodiment 1. The reflective polarizer 1123c of the transflective reflector 1120 is chromatic. The liquid crystal panel 1125 for switching is not particularly limited as long as it is switchable between the voltage applied state and the no-voltage applied state and can change the vibration direction of linearly polarized light having passed through the reflective polarizer 1123c in one of the states (for example, the voltage applied state). In Embodiment 5, the liquid crystal panel 1125 for switching may be, for example, a UV²A mode liquid crystal display panel for monochrome display with a phase difference of 320 nm. In a liquid crystal display panel for monochrome display, a color filter layer is excluded from a typical liquid crystal display panel for color display. The liquid crystal panel for switching may be a liquid crystal display mode liquid crystal panel such as a twisted nematic (TN) mode or in-plane switching (IPS) mode liquid crystal display.

As shown in FIG. 17, since the configuration of the display device of Embodiment 5 includes three absorptive polarizers 1113a, 1113b, and 1123a in total, a reduction in transmittance and yellow color shift of transmitted color are anticipated. In order to minimalize such performance deterioration, preferably, at least one of the absorptive polarizers 1113a, 1113b, and 1123a is adjusted to have a high transmittance or to be formed with a smaller amount of an ultraviolet ray (UV) absorber. Although adjusting the transmittance at a high value may cause a reduction in polarization degree, the performance of the display device is not adversely affected as long as the total system including the absorptive polarizers 1113a, 1113b, and 1123a and the reflective polarizer 1123c keeps a required polarization degree. The same shall apply to UV resistance performance.

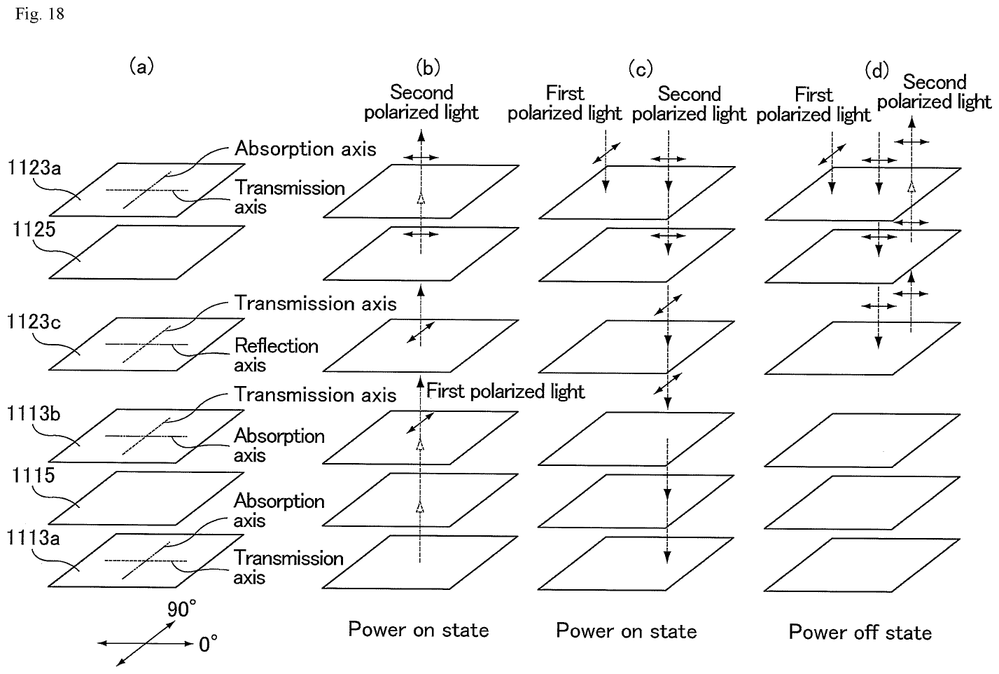

FIG. 18(a) is a drawing showing the configuration of a display device of Embodiment 5. FIG. 18(b) is an explanatory view showing the operation principle of the display state of the display device of Embodiment 5 from a viewpoint of display light. FIG. 18(c) is an explanatory view showing the operation principle of the display state of the display device of Embodiment 5 from a viewpoint of external light. FIG. 18(d) is an explanatory view showing the operation principle of the non-display state of the display panel of the display device of Embodiment 5. In Embodiment 5, a power on/off state means, unless otherwise specified, not the on/off state of the liquid crystal panel for switching (whether the azimuth of incident linearly polarized light is rotated by 90° or not), but the power on/off state of the liquid crystal display panel (whether display is performed or not).

First, a remaining problem of the display device of Embodiment 1 is described. In the power on state in Embodiment 1, only the behavior of the display light was described referring to a principle explanatory view. Actually, even in the power on state, external light is usually incident on the display panel from the viewer side. Thus, a viewer sees reflection of external light along with display light. The mechanism of this reflection is exactly the same as that of the non-display state of the display panel described referring to the principle explanatory view. Such unnecessary reflected light reduces the contrast ratio of the display panel in the display state to cause a reduction in visibility. This is because the reflected light causes a region providing black display to be unexpectedly bright.

Embodiment 5 is proposed to solve this problem. In the power on state, light emitted from the liquid crystal display panel is linearly polarized light vibrating in the 90° direction (in FIG. 18(b), shown as first polarized light) and passes through the reflective polarizer 1113b whose transmission axis is set to 90° with little loss. Thus, the display device of Embodiment 5 achieves display with a high luminance despite including the transflective reflector. Then, the linearly polarized light passes through the liquid crystal panel 1125 for switching in the on state (a state that can rotate the azimuth of linearly polarized light by 90° in the liquid crystal panel for switching, also referred to as a Δ/2 condition), so that the azimuth of the linearly polarized light is rotated by 90° and the light finally passes through the absorptive polarizer 1123a as second polarized light.

Simultaneously in the power on state, linearly polarized light vibrating in the 90° direction (shown as first polarized light in FIG. 18(c)) incident on the transflective reflector from the viewer side is absorbed by the absorptive polarizer 1123a whose transmission axis is set to 0°, i.e., whose absorption axis is set to 90°. Meanwhile, linearly polarized light vibrating in the 0° direction (shown as second polarized light in FIG. 18(c)) passes through the absorptive polarizer 1123a whose transmission axis is set to 0°, and the azimuth of the light is rotated by 90° by the liquid crystal panel 1125 for switching in the on state, and the light passes through the reflective polarizer 1123c whose transmission axis is set to 90°. Thus, the display device of Embodiment 5 causes no diffuse reflection of external light to achieve good visibility of the display panel in the display state.

Next, the power off state is discussed. Here, the liquid crystal panel 1125 for switching is also brought to the off state (the state not altering the polarization state; also referred to as a zero condition) in advance. Linearly polarized light vibrating in the 0° direction (shown as second polarized light in FIG. 18(d)) incident on the transflective reflector from the viewer side passes through the liquid crystal panel 1125 for switching in the off state while holding the polarization state. Then, almost all the amounts of the light is reflected by the reflective polarizer 1123c and passes through the liquid crystal panel for switching in the off state and the absorptive polarizer 1123a whose transmission axis is set to 0° to be emitted to the viewer side. Thus, the display device of Embodiment 5 with the display panel in the non-display state has a diffuse reflection surface similarly to the case of Embodiment 1.

As described, in Embodiment 5, a half of light incident on the display device from outside is absorbed by the absorptive polarizer 1123a and the rest half of light passes through the absorptive polarizer 1123a. In the display panel in the non-display state, light having passed through the absorptive polarizer 1123a is reflected by the reflective polarizer 1123c. In the display panel in the display state, light having passed through the absorptive polarizer 1123a passes through the reflective polarizer 1123c and is absorbed inside the display panel. Accordingly, the display device of Embodiment 5 in the display state of the display panel achieves, in addition to the effects of Embodiment 1, no diffuse reflection of external light, sufficient prevention of reflection, and display of an image with good visibility. Additionally, the contrast ratio is much better.

The display device of Embodiment 5 is particularly effective when applied to apparatuses used in bright places, and especially effective when applied to mobile devices such as smartphones, tablet PCs, and desktop PCs. This configuration may be applied to Embodiments 2 to 4.

### REFERENCE SIGNS LIST

1: Display device
2: Electronic apparatus
10, 110, 210, 310, 410, 510, 610, 710, 810, 910, 1010, 1110: Liquid crystal display panel
11, 111, 211, 311, 811, 911, 1011, 1111: Backlight
13a, 13b, 113a, 113b, 213a, 213b, 313a, 313b, 813a, 813b, 913a, 913b, 1013a, 1013b, 1113a, 1113b, 1123a: Absorptive polarizer
15, 115, 215, 315, 815, 915, 1015, 1115: Liquid crystal cell
20, 120, 220, 320, 420, 520, 620, 720, 820, 920, 1020, 1120: Transflective reflector
23c, 123c, 223c, 423c, 523c, 623c, 723c, 823, 923, 1023, 1123c: Reflective polarizer
27, 227a, 227b, 327, 427, 527, 627, 727, 827c, 927a, 927b, 1027, 1127: Adhesive layer
29, 129, 229, 329, 429, 529, 629, 729, 829, 929, 1029c: Front surface plate
127d: Diffusing adhesive layer
228: Diffusion sheet
323dc: Reflective polarizer with a diffusing function
522: Antireflection layer
624: Transparent resin
926: Chromatic sheet
1125: Liquid crystal panel for switching
BM: Light-shielding layer
C: Case
RL: Reflective layer

1. A display device comprising:
a display panel; and
a transflective reflector disposed on a viewing surface side of the display panel,
the transflective reflector including a reflective polarizer,
the reflective polarizer being chromatic and/or the transflective reflector further including a chromatic layer on a side closer to the viewing surface than the reflective polarizer.

2. The display device according to claim 1,
wherein the transflective reflector satisfies a proportion of a minimum reflectance to a maximum reflectance in a wavelength band from 400 to 700 nm of 5% to 50%.

3. The display device according to claim 1,
wherein the transflective reflector in a plan view has a reflectance and/or a chromaticity changing in one direction in a wavelength band from 400 to 700 nm.

4. The display device according to claim 1,
wherein the reflective polarizer is chromatic.

5. The display device according to claim 1,
wherein the transflective reflector further includes, on a side closer to the viewing surface than the reflective polarizer, at least one selected from the group consisting of a chromatic adhesive layer, a chromatic sheet, and a chromatic front surface plate.

6. The display device according to claim 1,
wherein the display device includes a light-shielding layer in a frame region on a back surface side of the reflective polarizer.

7. The display device according to claim 1,
wherein the display device includes an antireflection film on at least one selected from a back surface of the transflective reflector and a viewing surface of the display panel.

8. The display device according to claim 1,
wherein the display device includes a transparent resin filling a space between the transflective reflector and the display panel.

9. The display device according to claim 6,
wherein the display device includes a reflective layer between the reflective polarizer and the light-shielding layer.

10. The display device according to claim 9,
wherein the reflective layer has a reflectance in a wavelength band from 400 to 700 nm falling within a range of 1% to 10%.

11. The display device according to claim 1,
wherein the transflective reflector further includes a switching portion on a side closer to the viewing surface than the reflective polarizer, and
the switching portion is configured to be switchable between a state of transmitting light from the viewing surface side of the display device to the display panel and a state of not transmitting light from the viewing surface side of the display device to the display panel.

12. The display device according to claim 1,
wherein the display panel is a liquid crystal display panel or an organic electroluminescent display panel.

13. An electronic apparatus comprising the display device according to claim 1.

14. The electronic apparatus according to claim 13,
wherein the electronic apparatus further includes a chromatic case housing the display device, and
the chromatic case and the transflective reflector have a color difference ΔE of 0 or more and 6.5 or less.
